(19) United States
(12) Patent Application Publication
(10) Pub. No.: US 2025/0210567 A1
(43) Pub. Date: Jun. 26, 2025

(54) SEMICONDUCTOR PACKAGE

(71) Applicant: SAMSUNG ELECTRONICS CO., LTD, SUWON-SI (KR)

(72) Inventor: Kyungdon Mun, Suwon-si (KR)

(21) Appl. No.: 18/830,980

(22) Filed: Sep. 11, 2024

(30) Foreign Application Priority Data
Dec. 20, 2023 (KR) 10-2023-0186520

(51) Int. Cl. H01L 23/00; H01L 23/31; H01L 23/498; H01L 25/00; H01L 25/10

(52) U.S. Cl. CPC H01L 24/24; H01L 23/49822; H01L 24/20; H01L 24/25; H01L 25/105; H01L 23/3107; H01L 25/50; H01L 2224/215; H01L 2224/24146; H01L 2224/24226; H01L 2224/2518; H01L 2225/1041

(57) ABSTRACT

A semiconductor package includes a first redistribution layer (RDL) including a first redistribution wiring structure, a first bonding layer structure including a first bonding pattern structure disposed on the first RDL, a first semiconductor chip disposed on the first bonding layer structure, and a first mold disposed on the first bonding layer structure and a sidewall of the first semiconductor chip, and including an oxide.

### CROSS-REFERENCE TO RELATED APPLICATION

This application claims priority under 35 U.S.C. § 119 to Korean Patent Application No. 10-2023-0186520, filed on Dec. 20, 2023, in the Korean Intellectual Property Office (KIPO), the contents of which are herein incorporated by reference in their entirety.

### Technical Field

Example embodiments relate to a semiconductor package, and more particularly to a semiconductor package having a multi-layer bonding layer structure.

### Discussion of Related Art

In a fan out wafer level package (FOWLP), a conductive pad and a conductive bump may be interposed between a lower redistribution layer (RDL) and a lower semiconductor chip, and between an upper RDL and an upper semiconductor chip. The FOWLP may electrically connect the lower and upper RDLs and the lower and upper semiconductor chips to each other. The upper semiconductor chip and the lower RDL may be electrically connected to each other through a copper post and the upper RDL.

A bonding state between the conductive pad and the conductive bump, and a connection state between the copper post and the upper RDL may secure the electrical connection of the circuit pattern of the semiconductor package.

### SUMMARY

Example embodiments provide a semiconductor package having enhanced electrical characteristics.

Example embodiments provide a semiconductor package having a multi-layer bonding layer structure including a bonding pattern structure disposed between at a redistribution layer and a semiconductor chip.

According to example embodiments, there is provided a semiconductor package. The semiconductor package may include a first redistribution layer (RDL) including a first redistribution wiring structure, a first bonding layer structure including a first bonding pattern structure disposed on the first RDL, a first semiconductor chip disposed on the first bonding layer structure, and a first mold disposed on the first bonding layer structure and a sidewall of the first semiconductor chip, and including an oxide.

According to example embodiments, there is provided a semiconductor package. The semiconductor package may include an interposer, a first redistribution layer (RDL) disposed on the interposer, the first RDL including a first redistribution wiring structure being electrically connected to the interposer, a first bonding layer structure including a first bonding pattern structure disposed on an upper surface of the first RDL, the first bonding pattern structure being electrically connected to the first redistribution wiring structure, a first semiconductor chip disposed on an upper surface of the first bonding layer structure, the first semiconductor chip being electrically connected to the first bonding pattern structure, a first mold disposed on the first bonding layer structure and a sidewall of the first semiconductor chip, a via disposed on an upper surface of the first bonding pattern structure, the via being and being electrically connected to the first bonding pattern structure, a second RDL disposed on upper surfaces of the first mold, the first semiconductor chip, and the via, the second RDL including a second redistribution wiring structure, the second redistribution wiring structure being electrically connected to the via, a second bonding layer structure including a second bonding pattern structure disposed on an upper surface of the second RDL, the second bonding pattern structure being electrically connected to the second redistribution wiring structure, a second semiconductor chip disposed on an upper surface of the second bonding layer structure, the second semiconductor chip being electrically connected to the second bonding pattern structure, and a second mold disposed on the second bonding layer structure and a sidewall of the second semiconductor chip.

According to example embodiments, there is provided a semiconductor package. The semiconductor package may include a first redistribution layer (RDL) including a first redistribution wiring structure therein, a conductive connection member contacting a lower surface of the first redistribution wiring structure, a first bonding layer including a first bonding pattern therein and contacting an upper surface of the first RDL, a second bonding layer including a second bonding pattern therein and contacting an upper surface of the first bonding layer, the second bonding pattern contacting an upper surface of the first bonding pattern, a first semiconductor chip contacting an upper surface of the second bonding layer, the first semiconductor chip being electrically connected to the second bonding pattern, a first mold disposed on the second bonding layer, the first mold covering a sidewall of the first semiconductor chip and including an oxide, a via contacting an upper surface of the second bonding pattern, a second RDL disposed on the first mold, the first semiconductor chip, and the via, the second RDL including a second redistribution wiring structure therein, a third bonding layer including a third bonding pattern therein and contacting an upper surface of the second RDL, a fourth bonding layer including a fourth bonding pattern therein and contacting an upper surface of the third bonding layer, the fourth bonding pattern contacting an upper surface of the third bonding pattern, a second semiconductor chip contacting an upper surface of the fourth bonding layer, the second semiconductor chip being electrically connected to the fourth bonding pattern, and a second mold disposed on the fourth bonding layer, and the second mold covering a sidewall of the second semiconductor chip and including an oxide.

In the semiconductor package in accordance with example embodiments, the adhesion between the semiconductor chip and the RDL may be improved, and a void between the semiconductor chip and the RDL may be substantially prevented. Additionally, the vertical thickness of the semiconductor package may be reduced. Furthermore, the interface delamination between the mold covering the semiconductor chip and the via extending through the mold may be inhibited or prevented, and the electrical connection between the via and the RDL on the via may be improved.

### BRIEF DESCRIPTION OF THE DRAWINGS

FIG. 1 is a cross-sectional view illustrating a semiconductor package in accordance with example embodiments.

FIGS. 2 to 9 are cross-sectional views illustrating a method of manufacturing a semiconductor package in accordance with example embodiments.

FIG. 10 is a cross-sectional view illustrating a semiconductor package in accordance with example embodiments.

FIG. 11 is a cross-sectional view illustrating an electronic device in accordance with example embodiments.

### DETAILED DESCRIPTION

Hereinafter, example embodiments will be explained in detail with reference to the accompanying drawings. In the drawings, a direction substantially parallel to an upper surface of a wafer, an interposer or a substrate may be referred to as a horizontal direction, and a direction substantially perpendicular to the upper surface of the wafer, the interposer or the substrate may be referred to as a vertical direction.

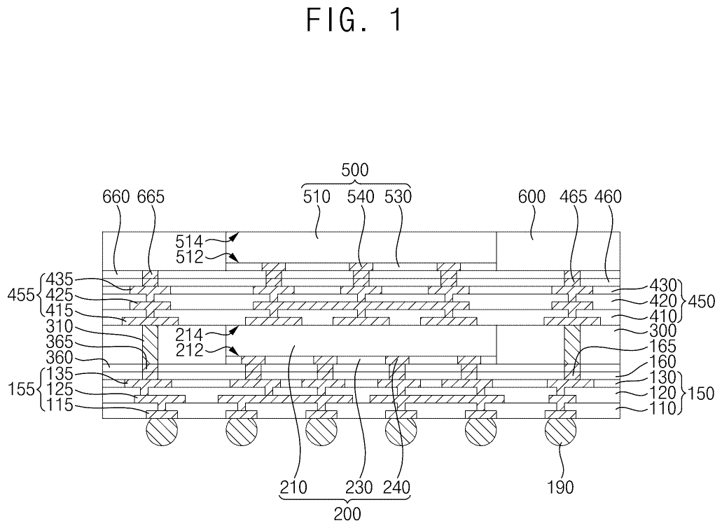

FIG. 1 is a cross-sectional view illustrating a semiconductor package in accordance with example embodiments.

Referring to FIG. 1, the semiconductor package may include a first bonding layer 160, a second bonding layer 360, a first semiconductor chip 200, a second redistribution layer (RDL) 450, a third bonding layer 460, a fourth bonding layer 660, and a second semiconductor chip 500. The first and second bonding layers 160 and 360, the first semiconductor chip 200, the second redistribution layer (RDL) 450, the third and fourth bonding layers 460 and 660, and the second semiconductor chip 500 may be sequentially stacked in the vertical direction.

The semiconductor package may further include a first mold 300, a second mold 600, a via 310 and a first conductive connection member 190.

In example embodiments, the first RDL 150 may include insulation layers stacked in the vertical direction. The first RDL 150 may include a first redistribution wiring structure 155 disposed in the insulation layers of the first RDL 150. The first redistribution wiring structure 155 may include, e.g., redistribution wirings, vias, contact plugs, conductive pads, etc.

Referring to FIG. 1, the first RDL 150 may include a first insulation layer 110, a second insulation layer 120, and a third insulation layer 130. The first to third insulation layers 110, 120, and 130 may be sequentially stacked in the vertical direction. The first redistribution wiring structure 155 may include a first conductive pad 115, a first redistribution wiring 125, and a second redistribution wiring 135. The first conductive pad 115, the first redistribution wiring 125, and the second redistribution wiring 135 may be sequentially stacked in the vertical direction. However, the inventive concept may not be limited thereto. For example, the first RDL 150 and the first redistribution wiring structure 155 may be variously modified. For example, the first RDL 150 may also include a different number of insulation layers, wherein the first RDL 150 may include less than three insulation layers or more than three insulation layers. In an example, the first redistribution wiring structure 155 may include redistribution wirings, vias, contact plugs, conductive pads, etc., having various vertical and/or horizontal layouts in the insulation layers.

Portions of the first redistribution wiring 125 and the second redistribution wiring 135 may serve as a second conductive pad and a third conductive pad, respectively. The first redistribution wiring 125 may contact an upper surface of the first conductive pad 115, and the second redistribution wiring 135 may contact an upper surface of the first redistribution wirings 125.

In example embodiments, each of the first to third insulation layers 110, 120 and 130 may include an organic material. The organic material may include a polymer, e.g., polyimide. The first conductive pad 115 and the first and second redistribution wirings 125 and 135 may include, e.g., aluminum, copper, tin, nickel, gold, or platinum, or an alloy thereof.

The first conductive connection member 190 may be disposed on a lower surface of the first RDL 150, and may contact the first conductive pad 115. In example embodiments, a plurality of first conductive connection members 190 may be spaced apart from each other in the horizontal direction according to a layout of the first conductive pads 115.

The first conductive connection member 190 may be mounted on and electrically connected to a package substrate, e.g., a printed circuit board (PCB), a mother board, etc. For example, while the first conductive connection member 190 may be disposed on a lower surface of the first RDL 150, the first conductive connection member 190 may be disposed on an upper surface of the package substrate.

The first conductive connection member 190 may include, e.g., a conductive bump, and the conductive bump may include, e.g., a metal such as copper, aluminum, nickel, etc., or solder that may be an alloy of tin, silver, copper and lead.

The first bonding layer 160 may be disposed on and contact an upper surface of the first RDL 150. A first bonding pattern 165 may be disposed in the first bonding layer 160. A plurality of first bonding patterns 165 may be spaced apart from each other in the horizontal direction in the first bonding layer 160. The first bonding patterns 165 may contact upper surfaces of the second redistribution wiring 135, respectively, of the first redistribution wiring structure 155.

The second bonding layer 360 may be disposed on and contact an upper surface of the first bonding layer 160. A second bonding pattern 365 may be disposed in the second bonding layer 360. A plurality of second bonding patterns 365 may be spaced apart from each other in the horizontal direction in the second bonding layer 360. The second bonding patterns 365 may contact upper surfaces of the first bonding patterns 165, respectively.

Each of the first and second bonding layers 160 and 360 may include an insulating material, e.g., silicon carbonitride, silicon oxide, etc. Each of the first and second bonding patterns 165 and 365 may include a metal, e.g., copper.

The first semiconductor chip 200 may include a first substrate 210 having first and second surfaces 212 and 214 disposed opposite to each other in the vertical direction, and a first insulating interlayer 230 disposed beneath the first surface 212 of the first substrate 210. The first insulating interlayer 230 may include one or more insulating interlayers, which may be sequentially stacked in the vertical direction beneath the first surface 212 of the first substrate 210.

FIG. 1 shows a first semiconductor chip 200 disposed on the first RDL 150, however, the inventive concept may not be limited thereto, and a plurality of first semiconductor chips 200 may be spaced apart from each other in the horizontal direction on the first RDL 150.

The first substrate 210 may include a semiconductor material, e.g., silicon, germanium, silicon-germanium, or a III-V group compound semiconductor, e.g., GaP, GaAs, GaSb, etc. In example embodiments, the first substrate 210 may be a silicon-on-insulator (SOI) substrate or a germanium-on-insulator (GOI) substrate.

A circuit device, e.g., a logic device or a memory device may be disposed beneath the first surface 212 of the first substrate 210, and may be covered by the first insulating interlayer 230. The logic device may include, e.g., a controller, and the memory device may include a volatile memory device, e.g., a DRAM device, an SRAM device, etc., or a non-volatile memory device, e.g., flash memory device, an EEPRM device, etc. The circuit device may include circuit patterns, e.g., transistors, capacitors, resistors, inductors, etc.

The first insulating interlayer 230 may include a first wiring structure 240. The first wiring structure 240 may include, e.g., wirings, vias, contact plugs, conductive pads, etc. FIG. 1 shows the first wiring structure 240 however, the inventive concept may not be limited thereto. For example, a plurality of first wiring structures 240 may be disposed in the first insulating interlayer 230.

In an example embodiment, a first through electrode (not shown) may extend through the first substrate 210 in the vertical direction, and may contact a portion of the circuit device beneath the first surface 212 of the first substrate 210 to be electrically connected thereto. Alternatively, the first through electrode may extend through the first substrate 210 and may contact a portion of the first wiring structure 240 in the first insulating interlayer 230 to be electrically connected to the first wiring structure 240.

Each interlayer of the first insulating interlayer 230 may include, e.g., silicon oxide or a low-k dielectric material, e.g., an oxide doped with carbon or fluorine. The first wiring structure 240 and the first through electrode include a conductive material, e.g., a metal, a metal nitride, a metal silicide, etc.

The first mold 300 may be disposed on the second bonding layer 360 and a sidewall of the first semiconductor chip 200. For example, the first mold 300 may cover the sidewall of the first semiconductor chip 200. In example embodiments, an upper surface of the first mold 300 may be substantially coplanar with an upper surface of the first semiconductor chip 200. The first mold 300 may include an oxide, e.g., silicon oxide.

The via 310 may extend through the first mold 300 in the vertical direction. The via 310 may contact an upper surface of the second bonding pattern 365 in the second bonding layer 360. In example embodiments, an upper surface of the via 310 may be substantially coplanar with the upper surface of the first mold 300. The via 310 may include a metal, e.g., copper, aluminum, etc.

The second RDL 450 may be disposed on the first semiconductor chip 200, the first mold 300, and the via 310. The second RDL 450 may include insulation layers and a second redistribution wiring structure 455 disposed in the insulation layers of the second RDL 450. The second redistribution wiring structure 455 may include, e.g., wirings, vias, contact plugs, conductive pads, etc.

Referring to FIG. 1, the second RDL 450 may include a fourth insulation layer 410, a fifth insulation layer 420, and a sixth insulation layer 430. The fourth to sixth insulating layers 410, 420, and 430 may be sequentially stacked in the vertical direction. The second redistribution wiring structure 455 may include a fourth conductive pad 415, a third redistribution wiring 425, and a fourth redistribution wiring 435. The fourth conductive pad 415, a third redistribution wiring 425, and a fourth redistribution wiring 435 may be sequentially stacked in the vertical direction. However, the inventive concept may not be limited thereto. For example, the second RDL 450 and the second redistribution wiring structure 455 may be variously modified. For example, the second RDL 450 may include a different number of insulation layers, wherein the second RDL 450 may include less than three insulation layers or more than three insulation layers. In an example, the second redistribution wiring structure 455 may include redistribution wirings, vias, contact plugs, conductive pads, etc., having various vertical and/or horizontal layouts in the insulation layers.

Portions of the third and fourth redistribution wirings 425 and 435 may serve as fifth and sixth conductive pads, respectively. The third redistribution wiring 425 may contact an upper surface of the fourth conductive pad 415, and the fourth redistribution wiring 435 may contact an upper surface of the third redistribution wiring 425.

In example embodiments, each of the fourth to sixth insulation layers 410, 420 and 430 may include an organic material. The organic material may include a polymer, e.g., polyimide. The fourth conductive pad 415 and the third and fourth redistribution wirings 425 and 435 may include, e.g., aluminum, copper, tin, nickel, gold, or platinum, or an alloy thereof.

The third bonding layer 460 may be disposed on and contact an upper surface of the second RDL 450. A third bonding pattern 465 may be disposed in the third bonding layer 460. A plurality of third bonding patterns 465 may be spaced apart from each other in the horizontal direction in the third bonding layer 460, and the third bonding patterns 465 may contact upper surfaces of the sixth conductive pads, respectively, of the second redistribution wiring structure 455.

The fourth bonding layer 660 may be disposed on and contact an upper surface of the third bonding layer 460. A fourth bonding pattern 665 may be disposed in the fourth bonding layer 660. A plurality of fourth bonding patterns 665 may be spaced apart from each other in the horizontal direction in the fourth bonding layer 660. The fourth bonding patterns 665 may contact upper surfaces of the third bonding patterns 465, respectively.

Each of the third and fourth bonding layers 460 and 660 may include an insulating material, e.g., silicon carbonitride, silicon oxide, etc., and each of the third and fourth bonding patterns 465 and 665 may include a metal, e.g., copper.

The second semiconductor chip 500 may include a second substrate 510 having a first surface 512 and a second surface 514 disposed opposite to each other in the vertical direction, and a second insulating interlayer 530 may be disposed beneath the first surface 512 of the second substrate 510. The second insulating interlayer 530 may include one or more insulating interlayers, which may be sequentially stacked in the vertical direction beneath the first surface 512 of the second substrate 510.

Referring to FIG. 1, a second semiconductor chip 500 may be disposed on the second RDL 450, however, the inventive concept may not be limited thereto, and a plurality of second semiconductor chips 500 may be spaced apart from each other in the horizontal direction on the second RDL 450.

The second substrate 510 may include a semiconductor material, e.g., silicon, germanium, silicon-germanium, or a III-V group compound semiconductor, e.g., GaP, GaAs, GaSb, etc. In example embodiments, the second substrate 510 may be a silicon-on-insulator (SOI) substrate or a germanium-on-insulator (GOI) substrate.

A circuit device, e.g., a logic device or a memory device may be disposed beneath the first surface 512 of the second substrate 510, and may be covered by the second insulating interlayer 530. The logic device may include, e.g., a controller, and the memory device may include a volatile memory device, e.g., a DRAM device, an SRAM device, etc., or a non-volatile memory device, e.g., flash memory device, an EEPRM device, etc. The circuit device may include circuit patterns, e.g., transistors, capacitors, resistors, inductors, etc.

The first insulating interlayer 230 may be disposed beneath the second insulating interlayer 530. The second insulating interlayer 530 may include a second wiring structure 540. The second wiring structure 540 may include, e.g., wirings, vias, contact plugs, conductive pads, etc. FIG. 1 shows the second wiring structure 540, however, the inventive concept may not be limited thereto. For example, a plurality of second wiring structures 540 may be disposed in the second insulating interlayer 530.

In an example embodiment, a second through electrode (not shown) may extend through the second substrate 510 in the vertical direction, and may contact a portion of the circuit device beneath the first surface 512 of the second substrate 510 to be electrically connected thereto. Alternatively, the second through electrode may extend through the second substrate 510 and may contact a portion of the second wiring structure 540 in the second insulating interlayer 530 to be electrically connected to the second wiring structure 540.

Each interlayer of the second insulating interlayer 530 may include, e.g., silicon oxide or a low-k dielectric material, e.g., an oxide doped with carbon or fluorine. The second wiring structure 540 and the second through electrode include a conductive material, e.g., a metal, a metal nitride, a metal silicide, etc.

The second mold 600 may be disposed on the fourth bonding layer 660 and a sidewall of the second semiconductor chip 500. For example, the second mold 600 may cover the sidewall of the second semiconductor chip 500. In example embodiments, an upper surface of the second mold 600 may be substantially coplanar with an upper surface of the second semiconductor chip 500. The second mold 600 may include an oxide, e.g., silicon oxide.

In some embodiments, the upper surface of the second mold 600 may be higher than the upper surface of the second semiconductor chip 500, and in this case, the second mold 600 may be disposed on the upper surface of the second semiconductor chip 500. For example, the second mold 600 may cover the upper surface of the second semiconductor chip 500. The second mold 600 may include, e.g., epoxy molding compound (EMC).

In the semiconductor package, the first semiconductor chip 200 and the first RDL 150 may be bonded with each other by a hybrid copper bonding (HCB) process, and the second semiconductor chip 500 and the second RDL 450 may be bonded with each other by an HCB process.

That is, the first semiconductor chip 200 and the first RDL 150 may be bonded with each other by the first and second bonding layers 160 and 360 and the first and second bonding patterns 165 and 365 respectively disposed therein, and the second semiconductor chip 500 and the second RDL 450 may be bonded with each other by the third and fourth bonding layers 460 and 660 and the third and fourth bonding patterns 465 and 665 respectively disposed therein.

The first semiconductor chip 200 and the second semiconductor chip 500 may each be electrically connected to the first conductive connection member 190. The first semiconductor chip 200 may be electrically connected to the first conductive connection member 190 by the first and second bonding patterns 165 and 365 and the first redistribution wiring structure 155, and the second semiconductor chip 500 may be electrically connected to the first conductive connection member 190 by the third and fourth bonding patterns 465 and 665, the second redistribution wiring structure 455, the via 310, the first and second bonding patterns 165 and 365 and the first redistribution wiring structure 155.

In an example embodiment, a semiconductor package may include a multi-layer bonding layer structure including a bonding pattern structure disposed between at a redistribution layer and a semiconductor chip.

In an example embodiment, the first and second bonding layers 160 and 360 may include substantially the same material, and the third and fourth bonding layers 460 and 660 may include substantially the same material. The first and second bonding layers 160 and 360 may collectively form a first bonding layer structure, and the third and fourth bonding layers 460 and 660 may collectively form a second bonding layer structure. The first bonding layer structure may be a first multi-layer bonding layer structure disposed between the first RDL 150 and the first semiconductor chip 200, and the second bonding layer structure may each be a second multi-layer bonding layer structure disposed between the second RDL 450 and the second semiconductor chip 500.

In an example embodiment, the first and second bonding layers 160 and 360 may be bonded to each other by a first HCB process, and the third and fourth bonding layers 460 and 660 may be bonded to each other by a second HCB process.

In an example embodiment, the first and second bonding patterns 165 and 365 may include substantially the same material, and the third and fourth bonding patterns 465 and 665 may include substantially the same material. The first and second bonding patterns 165 and 365 may collectively form a first bonding pattern structure, and the third and fourth bonding patterns 465 and 665 may collectively form a second bonding pattern structure.

In an example embodiment, the first and second bonding layers 160 and 360 may include different materials from each other, and the third and fourth bonding layers 460 and 660 may include different materials from each other. Additionally, the first and second bonding patterns 165 and 365 may include different materials from each other, and the third and fourth bonding patterns 465 and 665 may include different materials from each other.

In a comparative embodiment in which the first semiconductor chip 200 and the first RDL 150, or the second semiconductor chip 500 and the second RDL 450 are bonded with each other by a thermal compression bonding (TCB) process, a conductive pad including, e.g., gold or nickel and a conductive bump including, e.g., solder may be interposed therebetween. A thickness in the vertical direction of the conductive pad and the conductive bump may be greater than a thickness in the vertical direction of the first and second bonding layers 160 and 360, and a bonding state between the conductive pad and the conductive bump may be irregular.

Further, a non-conductive film (NCF) or a molding member including EMC that may surround the conductive pad and the conductive bump may be disposed between the first semiconductor chip 200 and the first RDL 150, and the NCF or the molding member may not entirely fill a space between the first semiconductor chip 200 and the first RDL 150 so that a void may be formed.

In example embodiments, the first semiconductor chip 200 and the first RDL 150 may be bonded with each other by an HCB process, and the vertical thickness of the first semiconductor chip 200 and the first RDL 150 may be reduced. Further, the second semiconductor chip 500 and the second RDL 450 may be bonded with each other by an HCB process, and the vertical thickness of the second semiconductor chip 500 and the second RDL 450 may be reduced. With a reduction in the vertical thickness of the first semiconductor chip 200 and the first RDL 150 and/or the second semiconductor chip 500 and the second RDL 450, an adhesion between the first semiconductor chip 200 and the first RDL 150 and/or the second semiconductor chip 500 and the second RDL 450 may increase, and the formation of the void may be substantially prevented.

In a comparative embodiment in which copper posts are formed on the first RDL 150, a molding member including EMC may be formed on the first RDL 150 to cover the copper posts and the first semiconductor chip 200, and a planarization process may be performed on the molding member exposing the copper posts. In this case, some of the copper posts may not exposed by the planarization process so that the second redistribution wiring structure 455 may not be electrically connected to the some of the copper posts, and an interface delamination may occur between the molding member and the copper posts.

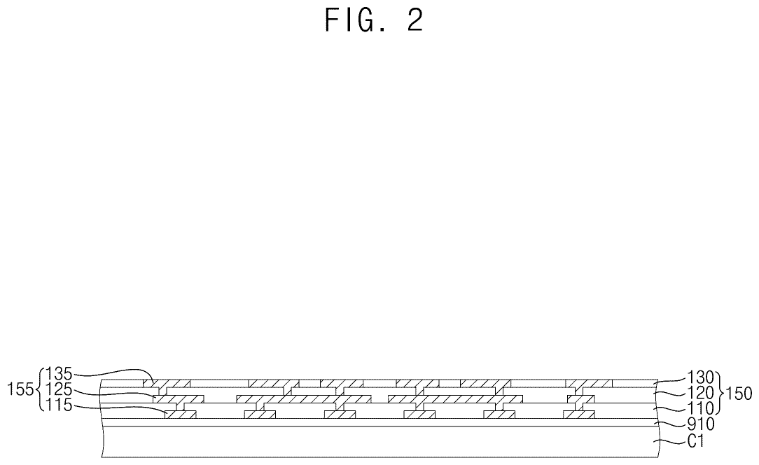

In example embodiments, and referring to FIGS. 2 to 9, the first mold 300 including, e.g., silicon oxide may be disposed on the first RDL 150, a fourth opening may be formed through the first mold 300, a via layer may be disposed in the fourth opening, and a planarization process may be performed on the via layer to form the via 310. In this case, the upper surface of the via 310 may be reliably exposed, an electrical connection between the second redistribution wiring structure 455 and the via 310 may be ensured, and an interface delamination between the first mold 300 including silicon oxide and the via 310 may be inhibited or prevented.

FIGS. 2 to 9 are cross-sectional views illustrating a method of manufacturing a semiconductor package in accordance with example embodiments.

Referring to FIG. 2, a first temporary bonding layer 910 may be attached on a first carrier substrate C1, and a first RDL 150 may be disposed on the first temporary bonding layer 910.

The first carrier substrate C1 may include, e.g., a non-metal or metal plate, a silicon substrate, a glass substrate, etc. The first temporary bonding layer 910 may include a material configured to lose adhesion due to irradiation of light or heating. For example, the first temporary bonding layer 910 may be a release tape.

In example embodiments, the first RDL 150 may include an insulation layers stacked in the vertical direction. and a first redistribution wiring structure 155 disposed in the insulation layers. The first redistribution wiring structure 155 may include, e.g., redistribution wirings, vias, contact plugs, conductive pads, etc.

Referring to FIG. 1, the first RDL 150 may include first to third insulation layers 110, 120 and 130 sequentially stacked in the vertical direction, and the first redistribution wiring structure 155 may include a first conductive pad 115, a first redistribution wiring 125 and a second redistribution wiring 135 sequentially stacked in the vertical direction. However, the inventive concept may not be limited thereto. For example, the first RDL 150 may include less than three insulation layers or more than three insulation layers, and the first redistribution wiring structure 155 may include redistribution wirings, vias, contact plugs, conductive pads, etc., having various vertical and/or horizontal layouts in the insulation layers.

A method for forming the first RDL 150 may including forming a first conductive pad 115 on the first temporary bonding layer 910, forming a first insulation layer 110 on the first temporary bonding layer 910 to cover the first conductive pad 115, and partially removing the first insulation layer 110 to form a first opening at least partially exposing an upper surface of the first conductive pad 115.

A first seed layer may be formed on an upper surface of the first insulation layer 110, a sidewall of the first opening and the upper surface of the first conductive pad 115 exposed by the first opening, e.g., an electroplating process or an electroless plating process may be performed to form a first redistribution wiring layer on the first seed layer. The first redistribution wiring layer may be patterned to form a first redistribution wiring 125. A portion of the first seed layer not covered by the first redistribution wiring 125 may be removed. The first redistribution wiring 125 may contact the upper surface of the first conductive pad 115 through the first opening, and a portion of the first redistribution wiring 125 may serve as a second conductive pad.

A second insulation layer 120 may be formed on the first insulation layer 110 to cover the first redistribution wiring 125. The second insulation layer 120 may be partially removed to form a second opening at least partially exposing an upper surface of the first redistribution wiring 125. A second seed layer may be formed on an upper surface of the second insulation layer 120, a sidewall of the second opening and the upper surface of the first redistribution wiring 125 exposed by the second opening. An electroplating process or a electroless plating process may be performed to form a second redistribution wiring layer on the second seed layer. The second redistribution wiring layer may be patterned to form a second redistribution wiring 135. A portion of the second seed layer not covered by the second redistribution wiring 135 may be removed. The second redistribution wiring 135 may contact the upper surface of the first redistribution wiring 125 through the second opening.

A third insulation layer 130 may be disposed on the second insulation layer 120 to cover the second redistribution wiring 135. A planarization process may be performed on the third insulation layer 130 exposing the second redistribution wiring 135. The third insulation layer 130 may cover a sidewall of the second redistribution wiring 135. A portion of the second redistribution wiring 135 may serve as a third conductive pad.

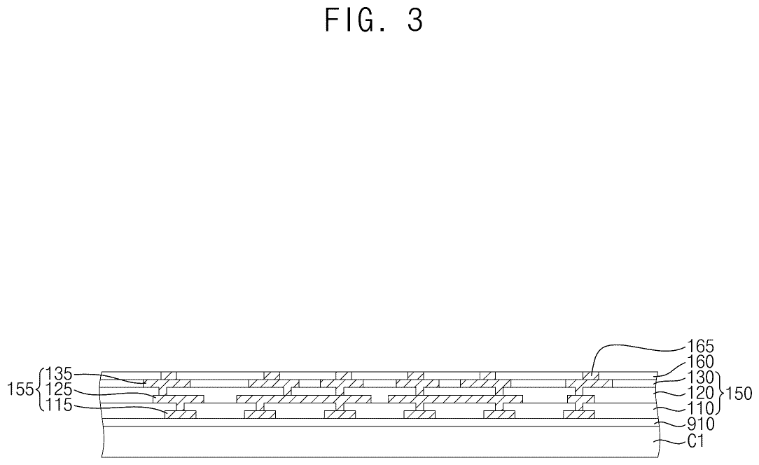

Referring to FIG. 3, a first bonding layer 160 containing a first bonding pattern 165 may be disposed on an upper surface of the first RDL 150 including the first redistribution wiring structure 155.

In example embodiments, the first bonding layer 160 may be formed by a deposition process, e.g., a chemical vapor deposition (CVD) process, an atomic layer deposition (ALD) process, etc.

The first bonding pattern 165 may be formed by forming a third opening extending through the first bonding layer 160 to expose an upper surface of the second redistribution wiring 135 included in the first redistribution wiring structure 155, forming a preliminary first bonding pattern on the second redistribution wiring 135 and the first bonding layer 160 to fill the third opening, and performing a planarization process on the preliminary first bonding pattern exposing the first bonding layer 160. The planarization process may include, e.g., a chemical mechanical polishing (CMP) process and/or an etch back process. In example embodiments, a plurality of first bonding patterns 165 may be spaced apart from each other in the horizontal direction.

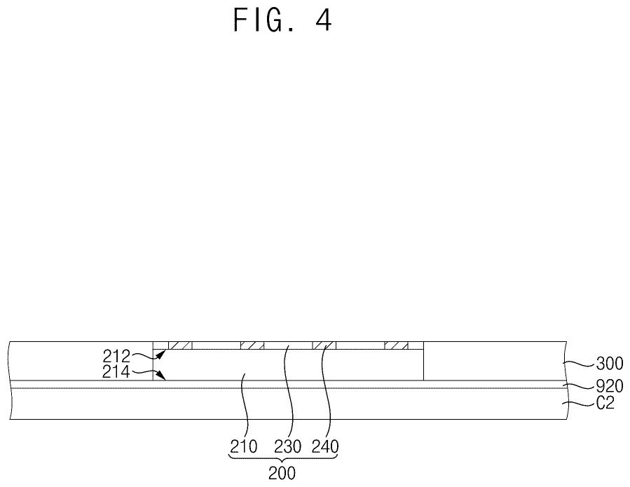

Referring to FIG. 4, a second temporary bonding layer 920 may be attached to a second carrier substrate C2, and a first semiconductor chip 200 may be mounted on the second temporary bonding layer 920.

The first semiconductor chip 200 may include a first substrate 210 having first and second surfaces 212 and 214 disposed opposite to each other in the vertical direction, and a first insulating interlayer 230 disposed on the first surface 212 of the first substrate 210. The first insulating interlayer 230 may include one or more insulating interlayers, which may be sequentially stacked in the vertical direction beneath the first surface 212 of the first substrate 210.

The first substrate 210 may include a semiconductor material, e.g., silicon, germanium, silicon-germanium, or a III-V group compound semiconductor, e.g., GaP, GaAs, GaSb, etc. In example embodiments, the first substrate 210 may be a silicon-on-insulator (SOI) substrate or a germanium-on-insulator (GOI) substrate.

A circuit device, e.g., a logic device or a memory device may be disposed beneath the first surface 212 of the first substrate 210, and may be covered by the first insulating interlayer 230. The logic device may include, e.g., a controller, and the memory device may include a volatile memory device, e.g., a DRAM device, an SRAM device, etc., or a non-volatile memory device, e.g., flash memory device, an EEPRM device, etc. The circuit device may include circuit patterns, e.g., transistors, capacitors, resistors, inductors, etc.

The first insulating interlayer 230 may contain a first wiring structure 240. The first wiring structure 240 may include a structure, e.g., wirings, vias, contact plugs, conductive pads, etc. The first wiring structure 240 may include one or more structures.

In an example embodiment, a first through electrode may extend through the first substrate 210 in the vertical direction, and may contact a portion of the circuit device on the first surface 212 of the first substrate 210 to be electrically connected thereto. Alternatively, the first through electrode may extend through the first substrate 210 and the first insulating interlayer 230, and may contact a portion of the first wiring structure 240 in the first insulating interlayer 230 to be electrically connected thereto.

A first mold layer may be disposed on the second temporary bonding layer 920. The first mold layer may cover the first semiconductor chip 200, and a planarization process may be performed on the first mold layer exposing the first semiconductor chip 200. The remaining portion of the first mold layer may be a first mold 300. The first mold 300 may cover a sidewall of the first semiconductor chip 200. The first mold layer may include an oxide, e.g., silicon oxide, and the planarization process may include, e.g., a CMP process and/or an etch back process.

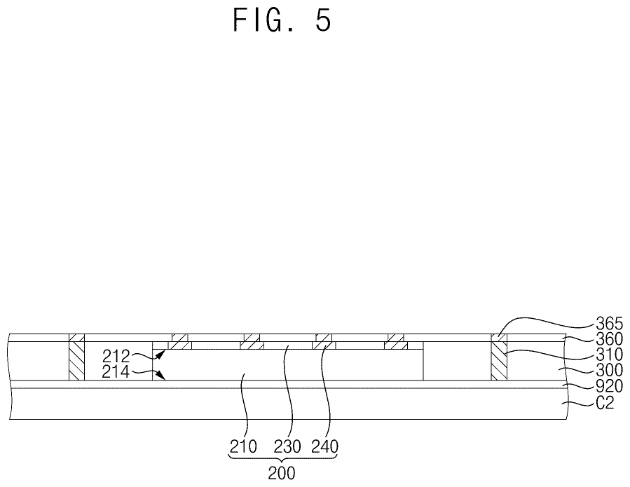

Referring to FIG. 5, a fourth opening may be formed through the first mold 300 exposing the second temporary bonding layer 920, and a via 310 may be disposed in the fourth opening.

The via 310 may be formed by forming a via layer on the first mold 300 and the first semiconductor chip 200 to fill the fourth opening, and a performing a planarization process on the via layer exposing the first mold 300. In example embodiments, a plurality of vias 310 may be spaced apart from each other in the horizontal direction.

A second bonding layer 360 containing a second bonding pattern 365 may be formed on the first mold 300, the first semiconductor chip 200 and the via 310.

The second bonding pattern 365 may be formed by forming a second bonding layer 360, forming a fifth opening through the second bonding layer 360 exposing the first wiring structure 240 in the first semiconductor chip 200 and an upper surface of the via 310 in the first mold 300, forming a preliminary second bonding pattern on the first wiring structure 240, the via 310, and the second bonding layer 360 to fill the fifth opening, and performing a planarization process on the preliminary second bonding pattern exposing the second bonding layer 360. In example embodiments, a plurality of second bonding patterns 365 may be spaced apart from each other in the horizontal direction.

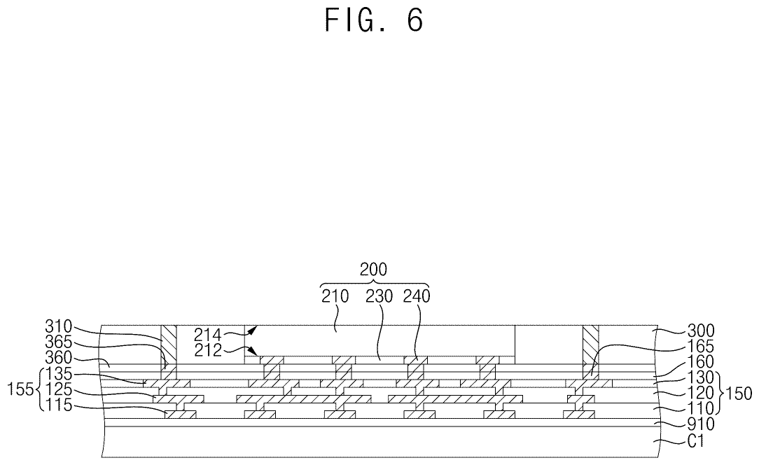

Referring to FIG. 6, structures on the first carrier substrate C1 may be bonded with structures on the second carrier substrate C2 by an HCB process.

For example, one of the first carrier substrate C1 or the second carrier substrate C2 may be flipped such that the first bonding layer 160 of the first carrier substrate C1 may face the second bonding layer 360 of the second carrier substrate C2. The second bonding layer 360 may be bonded with the first bonding layer 160 on the first carrier substrate C1 so that the structures on the first and second carrier substrates C1 and C2 may be bonded with each other. The second bonding patterns 365 in the second bonding layer 360 may contact the first bonding patterns 165, respectively, in the first bonding layer 160.

The second temporary bonding layer 920 attached to the second carrier substrate C2 may be separated from the first mold 300, the first semiconductor chip 200, and the via 310 so that the second carrier substrate C2 may be divided from the structure on the first carrier substrate C1. With the second carrier substrate C2 removed, the first mold 300, the first semiconductor chip 200, and the via 310 may be exposed.

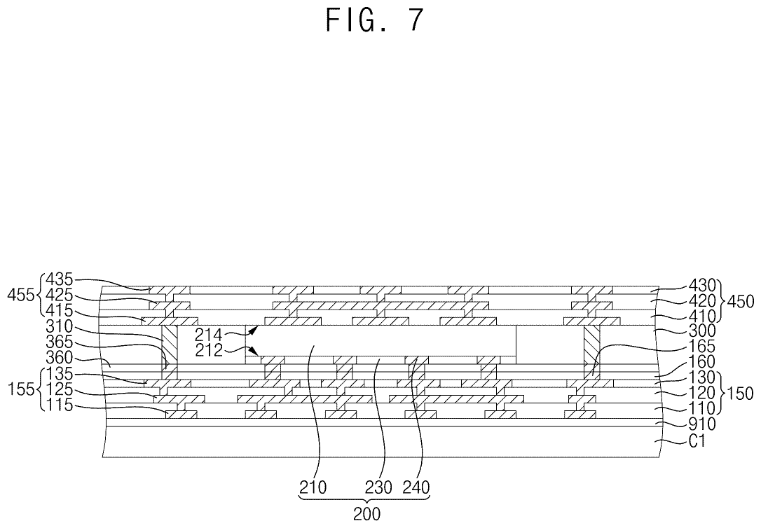

Referring to FIG. 7, a second RDL 450 may be formed on the first mold 300, the first semiconductor chip 200, and the via 310.

In example embodiments, the second RDL 450 may include insulation layers sequentially stacked in the vertical direction and a second redistribution wiring structure 455 therein. The second redistribution wiring structure 455 may include, e.g., redistribution wirings, vias, contact plugs, contact pads, etc.

Referring to FIG. 7, the second RDL 450 may include fourth to sixth insulation layers 410, 420 and 430 sequentially stacked in the vertical direction, and the second redistribution wiring structure 455 may include a fourth conductive pad 415, a third redistribution wiring 425, and a fourth redistribution wiring 435 sequentially stacked in the vertical direction, however, the inventive concept may not be limited thereto. For example, the second RDL 450 may include less than three insulation layers or more than three insulation layers, and the second redistribution wiring structure 455 may include redistribution wirings, vias, contact plugs, conductive pads, etc., having various vertical and/or horizontal layouts in the insulation layers.

Portions of the third and fourth redistribution wirings 425 and 435 may serve as fifth and sixth conductive pads, respectively.

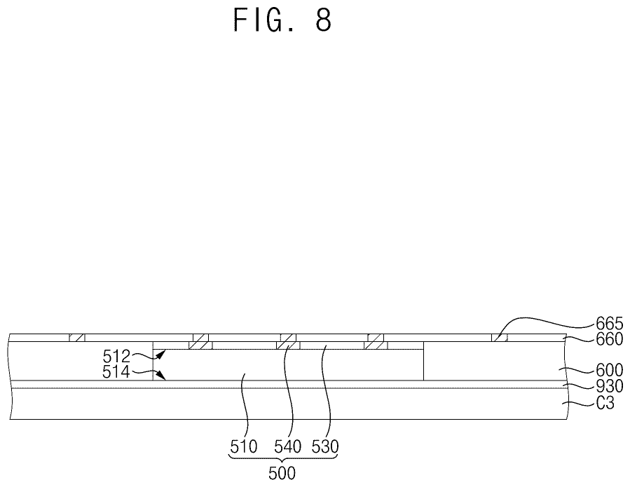

Referring to FIG. 8, processes substantially the same as or similar to those illustrated with respect to FIGS. 4 and 5 may be performed.

A third temporary bonding layer 930 may be attached to a third carrier substrate C3, and a second semiconductor chip 500 may be mounted on the third temporary bonding layer 930.

The second semiconductor chip 500 may include a second substrate 510 having a first surface 512 and a second surface 514 disposed opposite to each other in the vertical direction, and a second insulating interlayer 530 disposed on the first surface 512 of the second substrate 510. The second insulating interlayer 530 may include one or more insulating interlayers, which may be sequentially stacked in the vertical direction on the first surface 512 of the second substrate 510.

The second substrate 510 may include a semiconductor material, e.g., silicon, germanium, silicon-germanium, or a III-V group compound semiconductor, e.g., GaP, GaAs, GaSb, etc. In example embodiments, the second substrate 510 may be a silicon-on-insulator (SOI) substrate or a germanium-on-insulator (GOI) substrate.

A circuit device, e.g., a logic device or a memory device may be disposed on the first surface 512 of the second substrate 510. The second insulating interlayer 530 may be disposed on the first surface 512 of the second substrate 510. The second insulating interlayer 530 may cover the first surface 512 of the second substrate 510.

The second insulating interlayer 530 may contain a second wiring structure 540. The second wiring structure 540 may include a structure, e.g., wirings, vias, contact plugs, conductive pads, etc. The second wiring structure 540 may include one or more structures.

In an example embodiment, a second through electrode (not shown) may extend through the second substrate 510 in the vertical direction, and may contact a portion of the circuit device on the first surface 512 of the second substrate 510 to be electrically connected thereto. Alternatively, the second through electrode may extend through the second substrate 510 and the second insulating interlayer 530, and may contact a portion of the second wiring structure 540 in the second insulating interlayer 530 to be electrically connected thereto.

A second mold layer may be disposed on the third temporary bonding layer 930. The second mold layer may cover the second semiconductor chip 500, and a planarization process may be performed on the second mold layer exposing the second semiconductor chip 500. The remaining portion of the second mold layer may be a second mold 600. The second mold 600 may cover a sidewall of the second semiconductor chip 500. The second mold layer may include an oxide, e.g., silicon oxide.

A fourth bonding layer 660 containing a fourth bonding pattern 665 may be formed on the second mold 600 and the second semiconductor chip 500.

The fourth bonding pattern 665 may be formed by forming a sixth opening through the fourth bonding layer 660 exposing the second wiring structure 540 in the second semiconductor chip 500, forming a preliminary fourth bonding pattern on the second wiring structure 540 and the second bonding layer 360 to fill the sixth opening, and performing a planarization process on the preliminary fourth bonding pattern exposing the fourth bonding layer 660. In example embodiments, a plurality of fourth bonding patterns 665 may be spaced apart from each other in the horizontal direction.

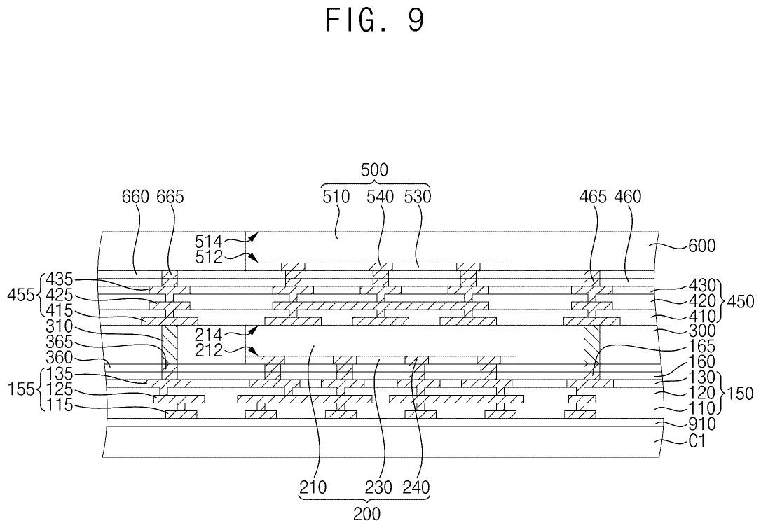

Referring to FIG. 9, processes substantially the same as or similar to those illustrated with respect to FIG. 6 may be performed so that structures on the first carrier substrate C1 and structures on the third carrier substrate C3 may be bonded with each other by an HCB process.

For example, a third bonding layer 460 including a third bonding pattern 465 therein may be disposed on the second RDL 450 that may include the second redistribution wiring structure 455 on the first carrier substrate C1.

The third bonding pattern 465 may be formed by forming a seventh opening through the third bonding layer 460 exposing the sixth conductive pad of the second redistribution wiring 435 in the second redistribution wiring structure 455, forming a preliminary third bonding pattern on the sixth conductive pad and the third bonding layer 460 to fill the seventh opening, and performing a planarization process on the preliminary sixth bonding pattern exposing the third bonding layer 460. In example embodiments, a plurality of third bonding patterns 465 may be spaced apart from each other in the horizontal direction.

One of the first carrier substrate C1 or the third carrier substrate C3 may be flipped, and the fourth bonding layer 660 may be bonded with the third bonding layer 460 on the first carrier substrate C1 so that the structures on the first and third carrier substrates C1 and C3 may be bonded with each other. The fourth bonding patterns 665 in the fourth bonding layer 660 may contact the third bonding patterns 465, respectively, in the third bonding layer 460.

The third temporary bonding layer 930 attached to the third carrier substrate C3 may be separated from the second mold 600 and the second semiconductor chip 500 so that the third carrier substrate C3 may be divided from the structure on the first carrier substrate C1. With the third carrier substrate C3 removed, the second mold 600 and the second semiconductor chip 500 may be exposed.

Referring back to FIG. 1, a fourth temporary bonding layer and a fourth carrier substrate may be attached to the second mold 600 and the second semiconductor chip 500, the fourth temporary bonding layer and the fourth carrier substrate may be flipped, and the first temporary bonding layer attached to the first carrier substrate C1 may be separated from the first RDL 150 so that the first carrier substrate C1 may be divided from the structure on the first carrier substrate C1.

A first conductive connection member 190 may be disposed on the first RDL 150, and the fourth carrier substrate may be cut by, e.g., a sawing process to be divided into a plurality of fourth substrates. During the sawing process, the first and second molds 300 and 600 stacked in the vertical direction on the fourth carrier substrate may also be cut such that the first and second molds 300 and 600 continue to cover sidewalls of the first and second semiconductor chips 200 and 500, respectively, on each of the fourth substrates.

According to an embodiment, a semiconductor package may be manufactured in accordance with aspects of the present disclosure.

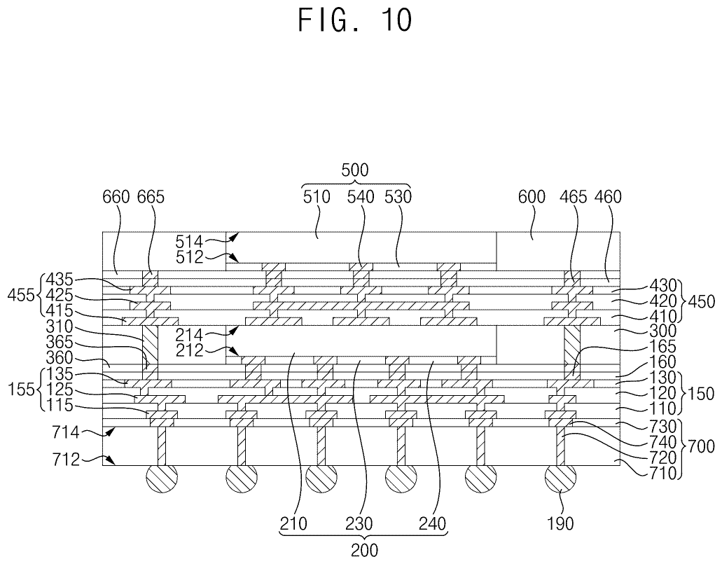

FIG. 10 is a cross-sectional view illustrating a semiconductor package in accordance with example embodiments. The semiconductor package of FIG. 10 may be substantially the same as or similar to that of FIG. 1, and repeated explanations thereof may be omitted. The semiconductor package of FIG. 10 may further include a first interposer.

Referring to FIG. 10, a first interposer 700 may be interposed between the first RDL 150 and the first conductive connection member 190.

In example embodiments, the first interposer 700 may include a first interposer substrate 710. The first interposer substrate 710 may include a first surface 712 and a second surface 714 disposed opposite to each other in the vertical direction. A third through electrode 720 may extend through the first interposer substrate 710 to contact an upper surface of the first conductive connection member 190. A seventh conductive pad 740 may be disposed on the second surface 714 of the first interposer substrate 710 and contacting an upper surface of the third through electrode 720, and a protective layer 730 may be disposed on the second surface 714 of the first interposer substrate 710 and covering a sidewall of the seventh conductive pad 740.

In example embodiments, the first interposer substrate 710 may include an inorganic material. The inorganic material may include an inorganic semiconductor material, e.g., silicon, germanium, silicon-germanium, etc., or glass.

The third through electrode 720 may include a metal, e.g., copper, aluminum, etc., or a metal nitride, e.g., titanium nitride, tantalum nitride, etc. The seventh conductive pad 740 may include, e.g., a metal, a metal nitride, a metal silicide, etc. The protective layer 730 may include an oxide, e.g., silicon oxide or a nitride, e.g., silicon nitride.

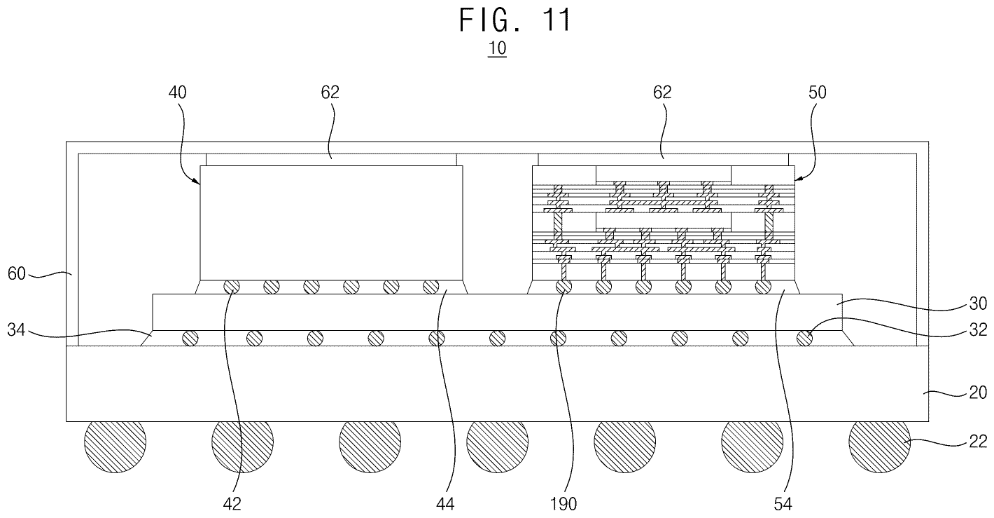

FIG. 11 is a cross-sectional view illustrating an electronic device in accordance with example embodiments. The electronic device of FIG. 11 may include the semiconductor package shown in FIG. 10 as a second semiconductor device 50.

Referring to FIG. 11, an electronic device 10 may include a package substrate 20, a second interposer 30, a first semiconductor device 40, and the second semiconductor device 50. The electronic device 10 may further include a first underfill member 34, a second underfill member 44, a third underfill member 54, a heat slug 60, and a heat dissipation member 62.

In example embodiments, the electronic device 10 may be a memory module having a 2.5 D package structure, and may include the second interposer 30 for electrically connecting the first and second semiconductor devices 40 and 50 to each other.

In example embodiments, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may be the semiconductor package of FIG. 10.

In example embodiments, the package substrate 20 may have an upper surface and a lower surface disposed opposite to each other in the vertical direction. For example, the package substrate 20 may be a printed circuit board (PCB). The printed circuit board may be a multi-layer circuit board having various circuits therein.

The second interposer 30 may be disposed on the package substrate 20 through a third conductive connection member 32. That is, the third conductive connection member 32 may be disposed between the second interposer 30 and the package substrate 20. In example embodiments, a planar area of the second interposer 30 may be smaller than a planar area of the package substrate 20. The second interposer 30 may be disposed within an area of the package substrate 20 in a plan view.

The second interposer 30 may be a silicon interposer or a redistribution interposer having a plurality of wirings therein. The first semiconductor device 40 and the second semiconductor device 50 may be connected to each other through the wirings in the second interposer 30 or electrically connected to the package substrate 20 through the third conductive connection member 32. The third conductive connection member 32 may include, e.g., a micro-bump. The silicon interposer may provide a high-density interconnection between the first and second semiconductor devices 40 and 50.

The first semiconductor device 40 may be disposed on the second interposer 30. The first semiconductor device 40 may be disposed on and bonded with the second interposer 30 by a TCB process. In this case, the first semiconductor device 40 may be disposed on the second interposer 30 such that an active surface on which conductive pads are formed may face downwardly toward the second interposer 30. The conductive pads of the first semiconductor device 40 may be electrically connected to conductive pads of the second interposer 30 through a fourth conductive connection member 42. For example, the fourth conductive connection member 42 may include, e.g., a micro-bump.

Alternatively, the first semiconductor device 40 may be disposed on the second interposer 30 by a wire bonding process, and in this case, the active surface of the first semiconductor device 40 may face upwardly.

The second semiconductor device 50 may be disposed on the second interposer 30, and may be spaced apart from the first semiconductor device 40 in the horizontal direction. The second semiconductor device 50 may be disposed on and bonded with the second interposer 30 by, e.g., a TCB process. In this case, conductive pads of the second semiconductor device 50 may be electrically connected to conductive pads of the second interposer 30 by the first conductive connection member 190.

FIG. 11 shows the first semiconductor device 40 and the second semiconductor device 50 disposed on the second interposer 30, however, the inventive concept may not be limited thereto, and a plurality of first semiconductor devices 40 and/or a plurality of second conductive devices 50 may be disposed on the second interposer 30.

In example embodiments, the first underfill member 34 may fill a space between the second interposer 30 and the package substrate 20, and the second underfill member 44 may fill a space between the first semiconductor device 40 and the second interposer 30, and the third underfill member 54 may fill a space between the second semiconductor device 50 and the second interposer 30, respectively.

The first to third underfill members 34, 44 and 54 may include a material having a relatively high fluidity to effectively fill a small space between the first and second semiconductor devices 40 and 50 and the second interposer 30, and fill a space between the second interposer 30 and the package substrate 20. For example, each of the first and second underfill members 34, 44 and 54 may include an adhesive containing an epoxy material.

In example embodiments, the heat slug 60 be formed on the package substrate 20 to thermally contact the first and second semiconductor devices 40 and 50. The heat dissipation member 62 may be disposed on an upper surface of each of the first and second semiconductor devices 40 and 50. The heat dissipation member 62 may include, e.g., thermal interface material (TIM). The heat slug 60 may thermally contact the first and second semiconductor devices 40 and 50 via the heat dissipation member 62.

A conductive pad may be formed at a lower portion of the package substrate 20. A second conductive connection member 22 may be disposed beneath the conductive pad. In example embodiments, a plurality of second conductive connection members 22 may be spaced apart from each other in the horizontal direction. The second conductive connection member 22 may be, e.g., a solder ball. The electronic device 10 may be disposed on a module board via the second conductive connection members 22 to form a memory module.

The foregoing is illustrative of example embodiments and is not to be construed as limiting thereof. Although example embodiments have been described, those skilled in the art will readily appreciate that many modifications are possible without materially departing from the novel teachings and advantages of the present invention. Accordingly, all such modifications are intended to be included within the scope of example embodiments as defined in the claims.

What is claimed is:

1. A semiconductor package comprising:
a first redistribution layer (RDL) including a first redistribution wiring structure;
a first bonding layer structure including a first bonding pattern structure disposed on the first RDL;
a first semiconductor chip disposed on the first bonding layer structure; and
a first mold disposed on the first bonding layer structure and a sidewall of the first semiconductor chip, and including an oxide.

2. The semiconductor package according to claim 1, further comprising:
a second RDL disposed on the first mold and the first semiconductor chip, the second RDL including a second redistribution wiring structure;
a second bonding layer structure including a second bonding pattern structure disposed on an upper surface of the second RDL;
a second semiconductor chip disposed on an upper surface of the second bonding layer structure; and
a second mold disposed on the second bonding layer structure and a sidewall of the second semiconductor chip, and including an oxide.

3. The semiconductor package according to claim 2, wherein the first bonding layer structure and the second bonding layer structure each include silicon carbonitride or silicon oxide, and the first bonding pattern structure and the second bonding pattern structure each include copper.

4. The semiconductor package according to claim 2, wherein the first bonding layer structure includes a first bonding layer and a second bonding layer stacked in a vertical direction, and the second bonding layer structure includes a third bonding layer and a fourth bonding layer stacked in the vertical direction.

5. The semiconductor package according to claim 2, wherein the first bonding pattern structure includes a first bonding pattern and a second bonding pattern stacked in a vertical direction, and the second bonding pattern structure includes a third bonding pattern and a fourth bonding pattern stacked in the vertical direction.

6. The semiconductor package according to claim 1, further comprising:
a second RDL disposed on the first mold and the first semiconductor chip, the second RDL including a second redistribution wiring structure; and
a via extending through the first mold in a vertical direction and contacting the first bonding pattern structure and the second redistribution wiring structure.

7. The semiconductor package according to claim 6, further comprising:
a second bonding layer structure including a second bonding pattern structure disposed on an upper surface of the second RDL;
a second semiconductor chip disposed on an upper surface of the second bonding layer structure; and
a second mold disposed on the second bonding layer structure and a sidewall of the second semiconductor chip, and including an oxide,
wherein the second semiconductor chip is electrically connected to the first redistribution wiring structure through the second bonding pattern structure, the second redistribution wiring structure, the via, and the first bonding pattern structure.

8. The semiconductor package according to claim 1, wherein the first semiconductor chip is electrically connected to the first redistribution wiring structure through the first bonding pattern structure.

9. The semiconductor package according to claim 1, wherein an upper surface of the first mold is substantially coplanar with an upper surface of the first semiconductor chip.

10. The semiconductor package according to claim 2, further comprising a first conductive connection member disposed beneath a lower surface of the first RDL, the first conductive connection member contacting the first redistribution wiring structure,
wherein an upper surface of the second mold is substantially coplanar with an upper surface of the second semiconductor chip.

11. The semiconductor package according to claim 1, further comprising:
an interposer contacting a lower surface of the first RDL; and
a first conductive connection member contacting a lower surface of the interposer.

12. A semiconductor package comprising:
an interposer;
a first redistribution layer (RDL) disposed on the interposer, the first RDL including a first redistribution wiring structure, and the first redistribution wiring structure being electrically connected to the interposer;
a first bonding layer structure including a first bonding pattern structure disposed on an upper surface of the first RDL, the first bonding pattern structure being electrically connected to the first redistribution wiring structure;
a first semiconductor chip disposed on an upper surface of the first bonding layer structure, the first semiconductor chip being electrically connected to the first bonding pattern structure;
a first mold disposed on the first bonding layer structure and a sidewall of the first semiconductor chip;
a via disposed on an upper surface of the first bonding pattern structure, the via being electrically connected to the first bonding pattern structure;
a second RDL disposed on upper surfaces of the first mold, the first semiconductor chip, and the via, the second RDL including a second redistribution wiring structure, and the second redistribution wiring structure being electrically connected to the via;
a second bonding layer structure including a second bonding pattern structure and disposed on an upper surface of the second RDL, the second bonding pattern structure being electrically connected to the second redistribution wiring structure;
a second semiconductor chip disposed on an upper surface of the second bonding layer structure, the second semiconductor chip being electrically connected to the second bonding pattern structure; and
a second mold disposed on the second bonding layer structure and a sidewall of the second semiconductor chip.

13. The semiconductor package according to claim 12, wherein the first bonding layer structure and the second bonding layer structure each include silicon carbonitride or silicon oxide, and the first bonding pattern structure and the second bonding pattern structure each include copper.

14. The semiconductor package according to claim 12, wherein the first bonding layer structure includes a first bonding layer and a second bonding layer stacked in a vertical direction, and the second bonding layer structure includes a third bonding layer and a fourth bonding layer stacked in the vertical direction.

15. The semiconductor package according to claim 12, wherein the first bonding pattern structure includes a first bonding pattern and a second bonding pattern stacked in a vertical direction, and the second bonding pattern structure includes a third bonding pattern and a fourth bonding pattern stacked in the vertical direction.

16. The semiconductor package according to claim 12, wherein the first mold includes an oxide.

17. The semiconductor package according to claim 12, wherein the interposer includes:
an interposer substrate;
a through electrode extending through the interposer substrate; and
a conductive pad disposed on the interposer substrate and electrically connected to the through electrode,
wherein the first redistribution wiring structure is electrically connected to the conductive pad.

18. The semiconductor package according to claim 17, further comprising a first conductive connection member disposed beneath a lower surface of the interposer substrate, the first conductive connection member being electrically connected to the through electrode.

19. A semiconductor package comprising:
a first redistribution layer (RDL) including a first redistribution wiring structure therein;
a conductive connection member contacting a lower surface of the first redistribution wiring structure;
a first bonding layer including a first bonding pattern therein and contacting an upper surface of the first RDL;
a second bonding layer including a second bonding pattern therein and contacting an upper surface of the first bonding layer, the second bonding pattern contacting an upper surface of the first bonding pattern;
a first semiconductor chip contacting an upper surface of the second bonding layer, the first semiconductor chip being electrically connected to the second bonding pattern;
a first mold disposed on the second bonding layer, the first mold covering a sidewall of the first semiconductor chip and including an oxide;
a via contacting an upper surface of the second bonding pattern;
a second RDL disposed on the first mold, the first semiconductor chip, and the via, the second RDL including a second redistribution wiring structure therein;
a third bonding layer including a third bonding pattern therein and contacting an upper surface of the second RDL;
a fourth bonding layer including a fourth bonding pattern therein and contacting an upper surface of the third bonding layer, the fourth bonding pattern contacting an upper surface of the third bonding pattern;
a second semiconductor chip contacting an upper surface of the fourth bonding layer, the second semiconductor chip being electrically connected to the fourth bonding pattern; and
a second mold disposed on the fourth bonding layer, the second mold covering a sidewall of the second semiconductor chip and including an oxide.

20. The semiconductor package according to claim 19, wherein the first bonding layer, the second bonding layer, the third bonding layer, and the fourth bonding layer each include silicon carbonitride or silicon oxide, and the first bonding pattern, the second bonding pattern, the third bonding pattern, and the fourth bonding pattern each include copper.
